(19) United States
(12) Patent Application Publication
(10) Pub. No.: US 2009/0016006 A1
(43) Pub. Date: Jan. 15, 2009

(54) Adjustable Support Mechanism For a Flat-Panel Display

(76) Inventor: Kenneth Moore Stothers, San Jose, CA (US)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 12/239,207

(22) Filed: Sep. 26, 2008

Related U.S. Application Data
(62) Division of application No. 11/170,394, filed on Jun. 28, 2005.

(51) Int. Cl. H05K 7/16

(52) U.S. Cl. 361/681

(57) ABSTRACT

An adjustable support mechanism for a flat-panel display is provided. The flat-panel display is attached to a diagnostic ultrasound system by way of the adjustable mechanism. The adjustable support mechanism allows the orientation of the flat-panel display to be tiltably, rotatably or vertically adjusted such that a user can maneuver the flat-panel display to a comfortable, ergonomic position.

### RELATED APPLICATIONS

The present patent document is a divisional of U.S. Pat. No. ______ (Ser. No. 11/170,394), filed Jun. 28, 2005, which is hereby incorporated by reference.

### BACKGROUND

This present invention relates to a support mechanism for a flat-panel display. In particular, this present invention relates to an adjustable support that allows a flat-panel display to be actuated to a user-selected orientation.

Typical diagnostic ultrasound systems have a large monitor provided for viewing the results of an ultrasound examination. The monitors are large and heavy, making it difficult to adjust the orientation of the monitor to be comfortably viewed by a user at different positions. Because some ultrasound examinations are performed by a user in a standing position as well as a seated position, the lack of adjustment of the monitor relative to a user's position can result in a user not being able to clearly see the ultrasound results. While some diagnostic ultrasound systems provide a flat-panel display, the display is not readily adjustable by the user.

Generally, the display for an ultrasound system is attached to a component cart such that the display is oriented in a substantially vertical manner. When the ultrasound system is moved from location to location, the upright display can make viewing around the display difficult.

### BRIEF SUMMARY

An adjustable support mechanism is provided for a flat-panel monitor where the adjustable support mechanism allows the user to position the flat-panel display in a comfortable viewing position when the user is located at various positions about the ultrasound system. A method for adjusting the orientation of a flat-panel display is also provided.

In one aspect, an adjustment mechanism for a flat-panel display is provided. The adjustment mechanism includes a base that receives a centering cam, wherein the centering cam includes at least one cam surface. A centering axle is attached to a connecting link, and the centering axle contacts at least one cam surface formed through the centering cam. The connecting link is also attached to an actuator arm that is, in turn, operatively connected to a tilt axle. The tilt axle is also connected to a swivel body. A flat-panel monitor is attached to the tilt axle of the adjustment mechanism. The flat-panel display is self-centering relative to the base.

In another aspect, a method for adjusting the orientation of a flat-panel display is provided. The method includes attaching a flat-panel display to an adjustable mechanism, wherein the adjustable mechanism includes a base, a centering cam operatively connected to the base, and a tilt axle operatively connected to the centering cam. The tilt axle is releasable engaged with the flat-panel display. Rotation of the tilt mechanism causes the flat-panel display to swivel, rotating the tilt axle about a horizontal axis causes the flat-panel display to tilt, and providing a vertical force to the tilt axle causes a height adjustment of the flat-panel display.

Advantages of the present invention will become more apparent to those skilled in the art from the following description of the preferred embodiments of the invention which have been shown and described by way of illustration. As will be realized, the invention is capable of other and different embodiments, and its details are capable of modification in various respects. Accordingly, the drawings and description are to be regarded as illustrative in nature and not as restrictive.

### BRIEF DESCRIPTION OF THE DRAWINGS

The components and the figures are not necessarily to scale, emphasis instead being placed upon illustrating the principles of the invention. Moreover, in the figures, like reference numerals designate corresponding parts throughout the different views.

FIG. 1 is one embodiment of an ultrasound component cart;

FIG. 2 is an alternative embodiment of an ultrasound component cart;

FIG. 3 is a front isometric view of a flat-panel display attached to one embodiment of an adjustable support mechanism;

FIG. 4 is a rear isometric view of the adjustable support mechanism of FIG. 3 having a portion cut away;

FIG. 5 is an exploded view of an adjustable support mechanism;

FIG. 6 is a top perspective view of a base for an adjustable support mechanism;

FIG. 7 is a bottom perspective view of the base of FIG. 6

FIG. 8 is an exploded view of a spline nut, spline shaft, pull-down member and a base;

FIG. 9 is a bottom rear isometric view of an upper portion of an adjustable support mechanism;

FIG. 10 is an isometric view of one embodiment of a centering cam;

FIG. 11 is an exploded view of an upper portion, lower portion, and gas spring of an adjustable support mechanism;

FIG. 12 is an isometric view of centering cam and a sleeve;

FIG. 13 is an exploded side view of the upper portion of an adjustable support mechanism;

FIG. 14 is a top rear isometric view of one embodiment of an adjustable support mechanism; and

FIG. 15 is a top rear isometric view of an alternative embodiment of an adjustable support mechanism.

### DETAILED DESCRIPTION OF THE DRAWINGS AND PRESENTLY PREFERRED EMBODIMENTS

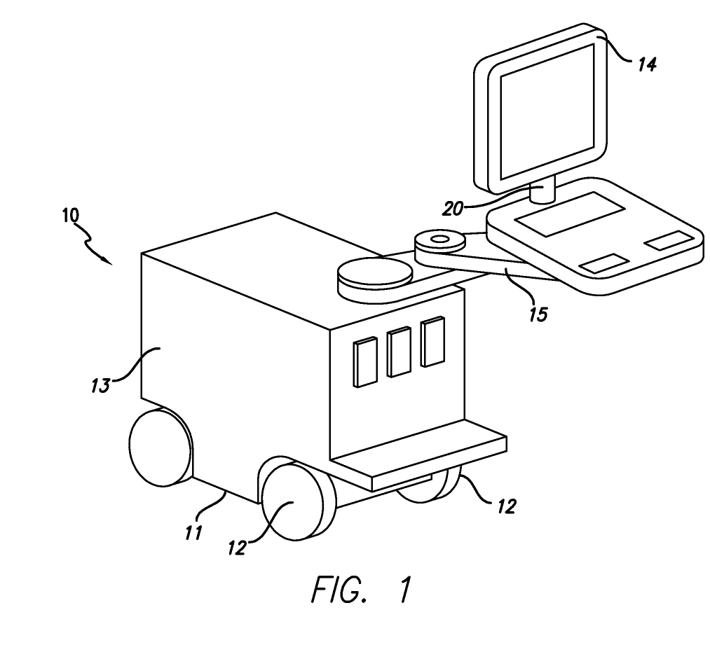

Referring to FIG. 1, one embodiment of the components of an ultrasound component stand 10 for a diagnostic ultrasound system having a support mechanism for adjusting the orientation of a flat-panel display screen is shown. While the remaining description is directed to an adjustable support mechanism for a flat-panel display for use in combination with an ultrasound system, the adjustment mechanism can be used in conjunction with any application having a flat-panel display including, for example, a laptop computer. The ultrasound component stand 10 includes a foundation 11, casters or wheels 12, and a housing 13. Fewer, different, or additional components may be included in the ultrasound component stand 10.

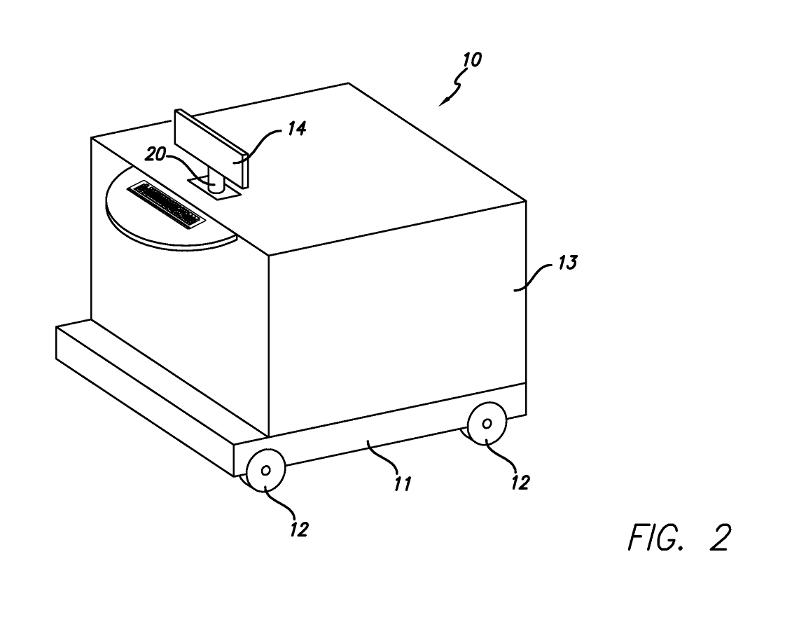

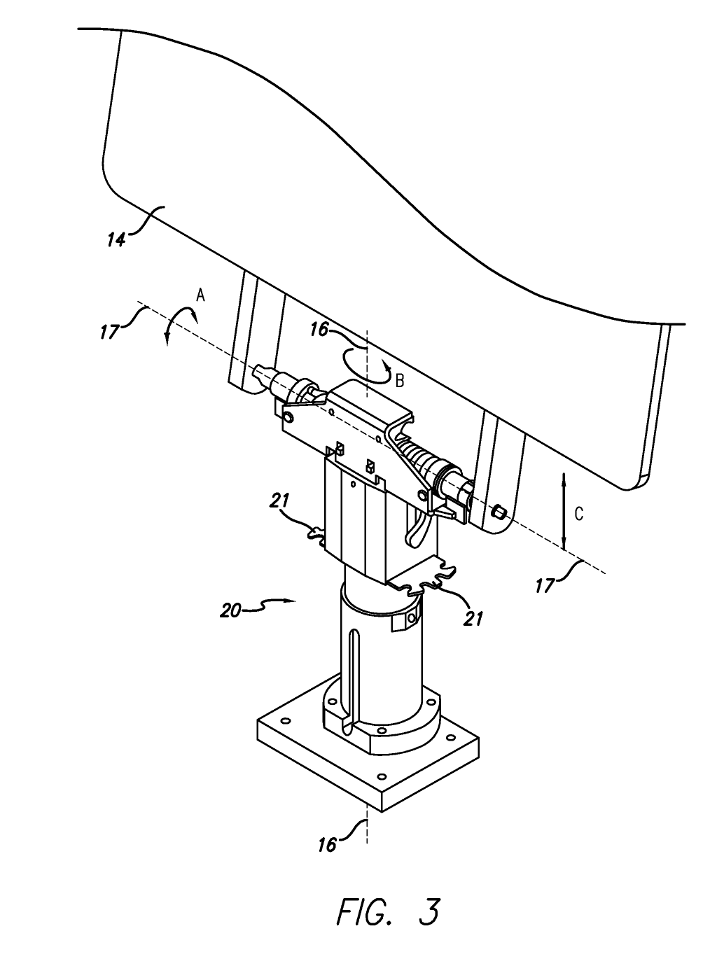

The wheels 12 of the component stand 10 are connected to the foundation 11, as illustrated in FIG. 1, to allow the component stand 10 to be easily transportable between various locations. The foundation 11 supports the entire system thereon and is configured to provide a stable foundation yet be small enough to fit within crowded rooms. The housing 13 is configured to enclose the processor (not shown) for the diagnostic ultrasound system so as to protect the components of the processor. A flat-panel display 14 is operatively connected to the housing 13, and the flat-panel display 14 is configured to provide a user with an electronic display of the ultrasound examination results. The flat-panel display 14 is attached to a support mechanism 20 that allows the flat-panel display to be adjustable in a variety of manners. In one embodiment, the support mechanism 20 is operatively attached to the housing 13 by way of a rotational mechanism 15, as shown in FIG. 1. In an alternative embodiment, the flat-panel display 14 connected to the support mechanism 20 that is rigidly connected to the housing 13, as illustrated in FIG. 2. The flat-panel display 14 is connected to the processor located within the housing 13 by way of electrical wiring (not shown). The wiring extends adjacent to the sides of the support mechanism 20 and is secured to the support mechanism 20 by way of cable clips 21, as shown in FIG. 3. The support mechanism 20 allows the orientation of the flat-panel display 14 to be adjusted relative to the housing 13. The support mechanism 20 may provide a variety of different orientations of the flat-panel display 14 such that when a user is located at different position relative to the housing 13 the flat-panel display 14 may be easily viewed.

The support mechanism 20 allows the flat-panel display 14 to be moveable relative to the housing 13, as shown in FIG. 3. The support mechanism 20 allows a user to position the flat-panel display 14 in a comfortable, ergonomically efficient position. The relative movements provided by the support mechanism 20 include, but are not limited to, tilt of the flat-panel display 14 in a fore/aft direction about a horizontal axis 17 with respect to the relative position of the flat-panel display 14, as indicated by the directional arrow A, swivel of the flat-panel display 14 about a vertical axis 16, as indicated by directional arrow B, and vertical height adjustment, as indicated by the directional arrow C, or any combination thereof. Fewer, different, or additional components or mechanisms may be included in the support mechanism 20, thereby providing additional manners of movement of the flat-panel display 14 relative to the housing 13. The support mechanism 20 provides a variety of user-selected orientations of the flat-panel display 14 such that users of different heights or in different positions, such as standing or seated, can adjust the flat-panel display 14 to a comfortable position.

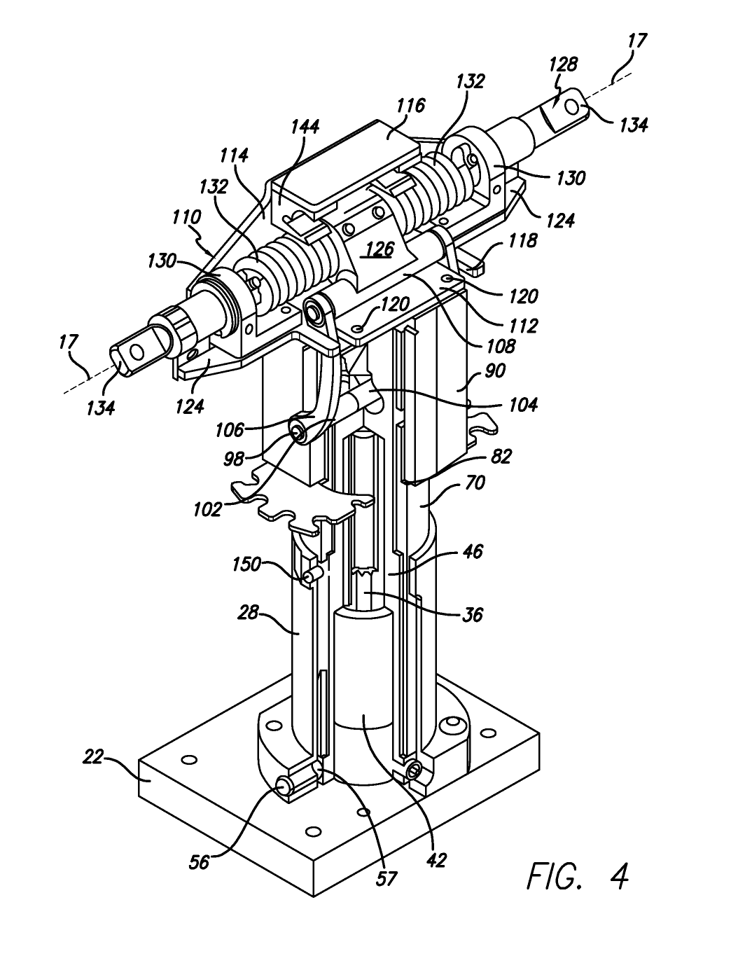

The support mechanism 20 includes a base 22 having a top surface 24 and a bottom surface 26, as shown in FIGS. 4-7. The base 22 is connected to the housing 13 in a substantially rigid manner by a plurality of bolts, but the base 22 can be attached to the housing 13 by any other connecting mechanism. In an alternative embodiment, the base 22 can be releasably connected to the housing 13 or the rotational mechanism 15, thereby allowing the support mechanism 20 and flat-panel display 14 to be removed and replaced or repaired when necessary.

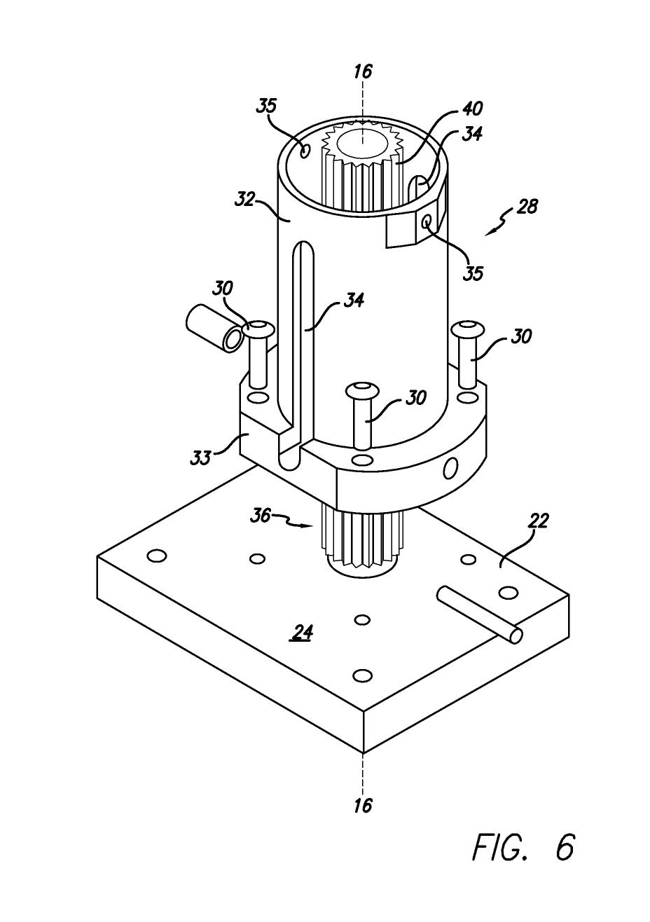

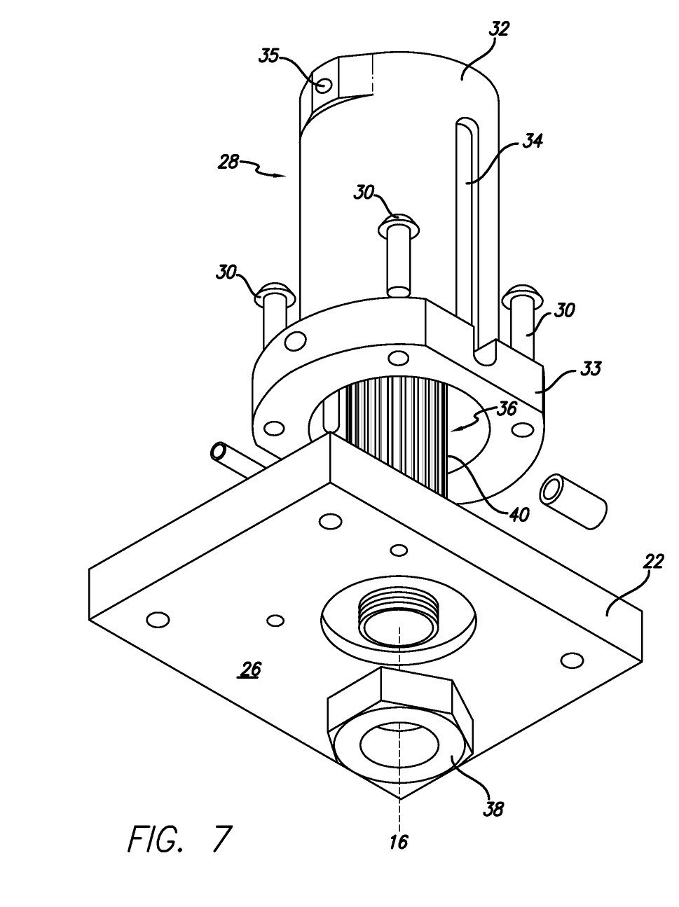

In one embodiment, the support mechanism 20 includes a pull-down member 28 that is attached to the top surface 24 of the base 22, as shown in FIGS. 4-7. The pull-down member 28 is attached to the base 22 by a plurality of bolts 30, but the pull-down member 28 can be attached to the base 22 by any other connecting mechanism. In an alternative embodiment, the pull-down member 28 and the base 22 are formed as a single component. The pull-down member 28 has a generally hollow cylindrical body 32 extending from a flange 33, wherein the flange 33 connects the pull-down member 28 to the top surface 24 of the base 22, as illustrated in FIG. 6. At least one elongated slot 34 is formed through the thickness of the cylindrical body 32 of the pull-down member 28, as shown in FIGS. 6-7. The slot 34 is formed in the pull-down member 28 and is oriented in a substantially parallel manner relative to the vertical axis 16. The pull-down member 28 also includes a pair of receiving apertures 35 located on opposing sides of the pull-down member 28.

As illustrated in FIGS. 6-7, a spline shaft 36 is disposed within the cylindrical body 32 of the pull-down member 28. The spline shaft 36 is secured to the base 22 by a nut 38, as shown in FIG. 7. In an alternative embodiment, the spline shaft 36 is rigidly attached directly to the housing 13. The spline shaft 36 is oriented such that the spline shaft 36 extends from the base 22 in a substantially parallel manner with the cylindrical body 32 of the pull-down member 28, as shown in FIG. 6, and the cylindrical body 32 of the pull-down member 28 is also aligned with the spline shaft 36 in a concentric manner. The spline shaft 36 is a hollow member having a splined, or pinioned, outer surface 40, wherein the grooves forming the splined outer surface 40 are oriented in a manner parallel with the vertical axis 16. The splined outer surface 40 of the spline shaft 36 is spaced-apart from the inner surface of the pull-down member 28.

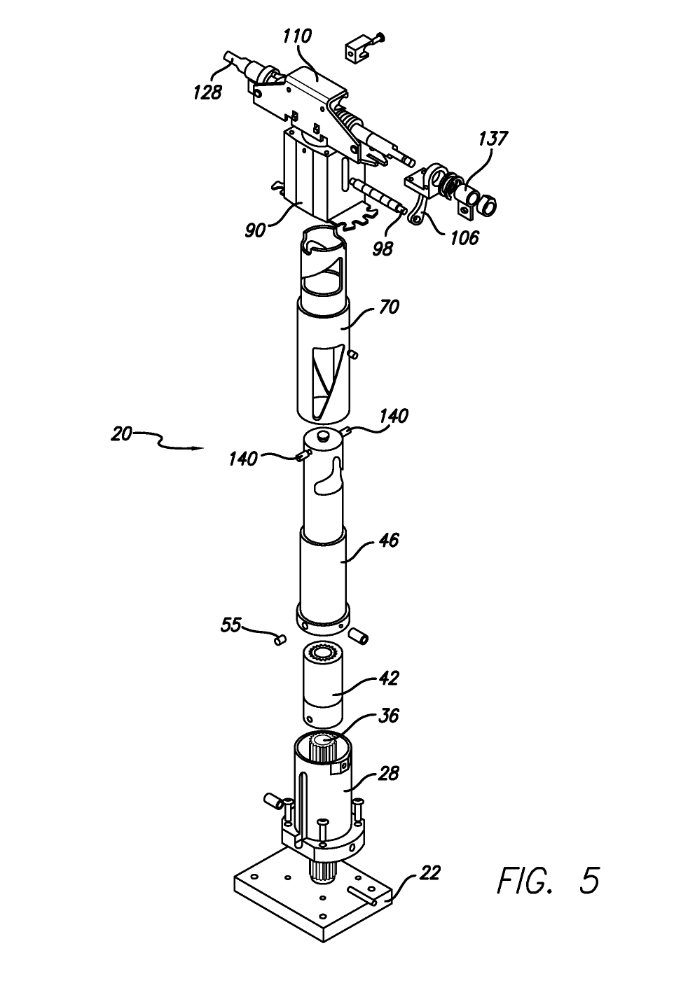

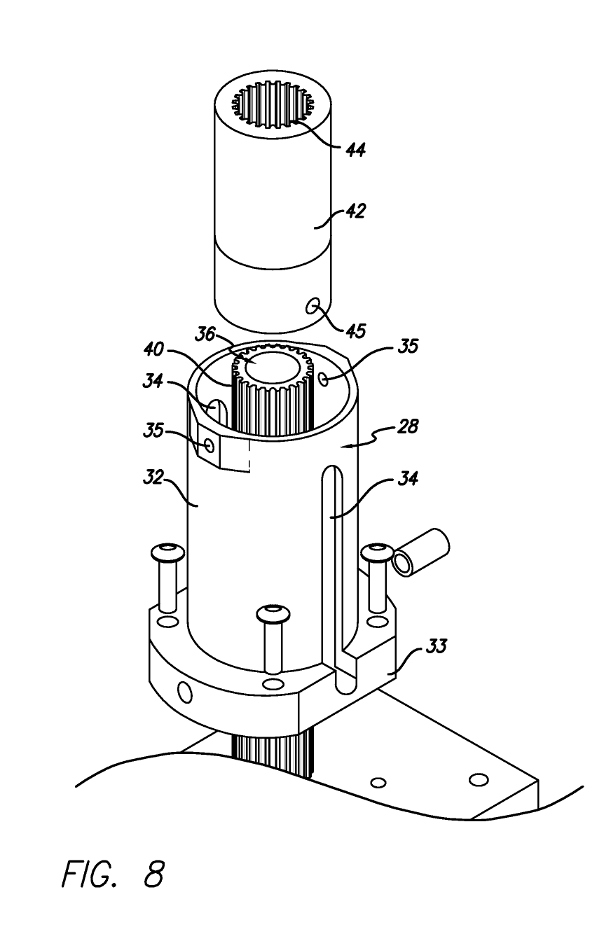

A spline nut 42, as shown in FIGS. 4-5 and 8-9, is disposed between the inner surface of the cylindrical body 32 of the pull-down member 28 and the spline shaft 36. The spline nut 42 has a splined, or pinioned, inner surface 44 having a plurality of grooves formed thereon that correspond to the splined outer surface 40 of the spline shaft 36. The spline nut 42 is located immediately adjacent to the spline shaft 36 such that the splined outer surface 40 of the spline shaft 36 is in abutting engagement with the splined inner surface 44 of the spline nut 42. The corresponding splined surfaces 40, 44 prevent rotation of the spline nut 42 about the vertical axis 16. The corresponding splined surfaces 40, 44 allow for the translation of the spline nut 42 relative to the spline shaft 36 in a substantially linear manner along the vertical axis 16, whereby the slots 34 limit the range of vertical movement. The spline nut 42 has at least one receiving aperture 45 formed therein, as illustrated in FIG. 8. The receiving aperture 45 has a depth sufficient to receive the first follower 55, as shown in FIG. 5.

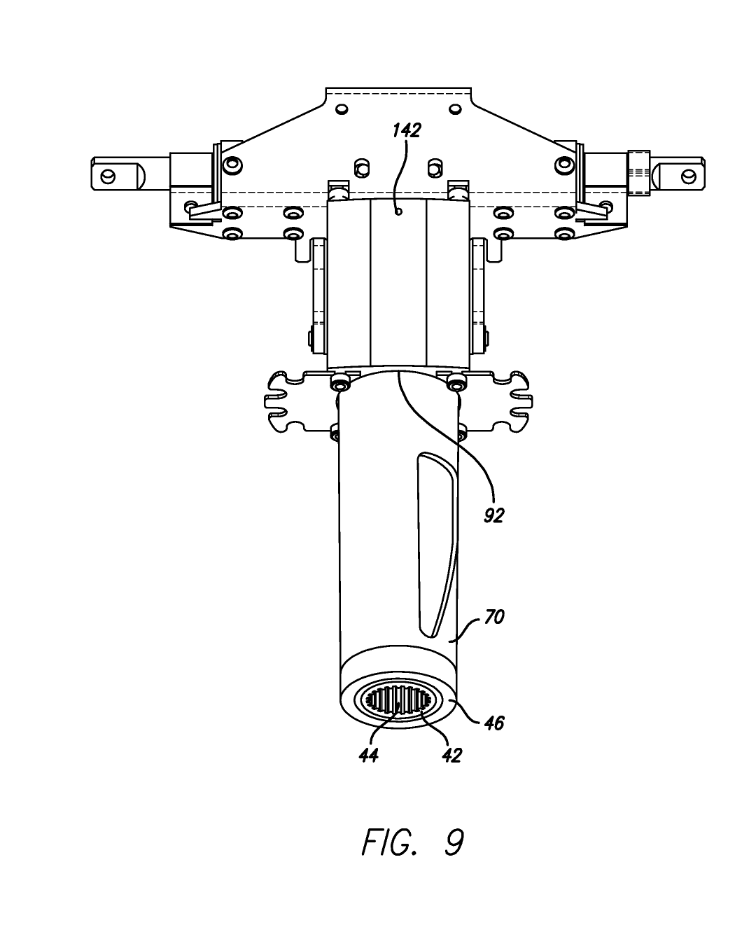

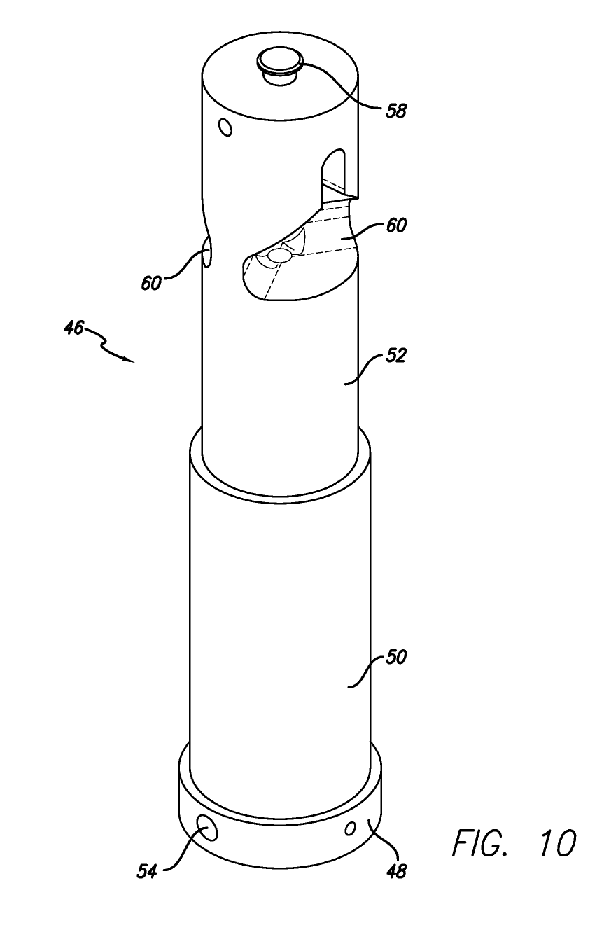

A centering cam 46 is disposed about the outer surface of the spline nut 42, as illustrated in FIGS. 9-10, in a concentric manner. The centering cam 46 is formed as a stepped structure having an attachment portion 48, a central portion 50, and a guide portion 52, as shown in FIG. 10. The attachment portion 48 has at least one aperture 54 formed therethrough. The aperture 54 of the attachment portion 48 receives a first follower 55 (FIG. 5). The first follower 55 is inserted through the aperture 54 of the attachment portion 48 of the centering cam 46 and is received in the receiving aperture 45 of the spline nut 42. When the support mechanism 20 is assembled, the centering cam 46 and the spline nut 42 are located between the inner surface of the pull-down member 28 and the splined outer surface 40 of the spline shaft 36, and the first follower 55 is of sufficient length to extend from the attachment portion 48 of the centering cam 46 such that the first follower 55 is disposed within the slot 34 (FIG. 8) in the cylindrical body 32 of the pull-down member 28. The first follower 55 translates between the ends of the slot 34, thereby providing upper and lower limits for the adjustable height. In one embodiment, the first follower 55 is a set screw that extends from the attachment portion 48.

The central portion 50 of the centering cam 46 is adjacent to the attachment portion 48 of the centering cam 46, as shown in FIGS. 9-10. The outer surface of the central portion 50 has a smaller diameter than the attachment portion 48, thereby creating a ledge, or lip, between these portions of the centering cam 46. The central portion 50 is hollow and is generally cylindrical in shape. The guide portion 52 of the centering cam 46 is located adjacent to the central portion 50 of the centering cam 46. The outer surface of the guide portion 52 has a smaller diameter than the central portion 50, thereby creating a ledge, or lip, between these portions of the centering cam 46. The guide portion 52 of the centering cam 46 has a generally cylindrical shape. A knob 58 from a gas spring 62 extends from the top surface of the guide portion 52 of the centering cam 46. In one embodiment, the guide portion 52 of the centering cam 46 has a pair of apertures formed therein to form a pair of cam surfaces 60, as shown in FIG. 10, wherein the cam surfaces 60 are mirror images thereof. In an alternative embodiment, the guide portion 52 of the centering cam 46 includes a single cam surface 60 for receiving a centering axle 98 (FIG. 4).

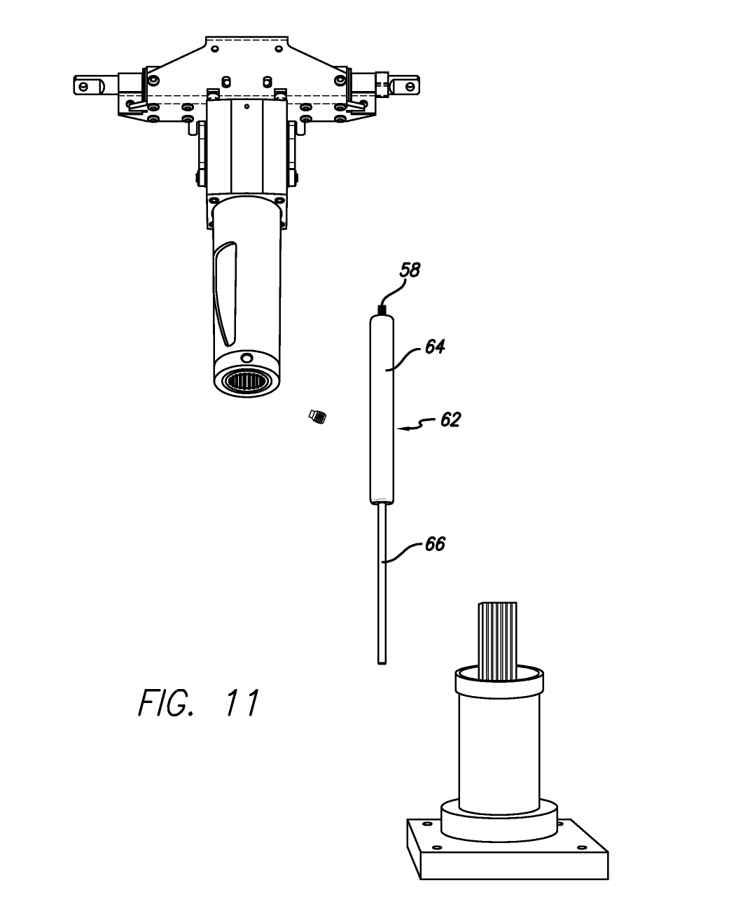

A gas spring 62, as shown in FIG. 11, having a chamber 64, a rod 66, and a knob 58 is disposed within the spline shaft 36 such that the rod 66 is received in a recess (not shown) in the lower end of the spline shaft 36. The knob 58 of the gas spring 62 extends from the centering cam 46 and is received in a keyhole aperture (not shown) located in the tilt bracket 110 (FIG. 3) such that as the height of the flat-panel display 14 is adjusted, the gas spring 62 is actuated, thereby providing vertical support to the height adjustment aspect of the support mechanism 20 so as to maintain the desired vertical height of the flat-panel display 14. The chamber 64 of the gas spring 62 has a substantially constant force across the vertical range of movement of the flat-panel display 14 so as to provide a counter-balance to the flat-panel display 14.

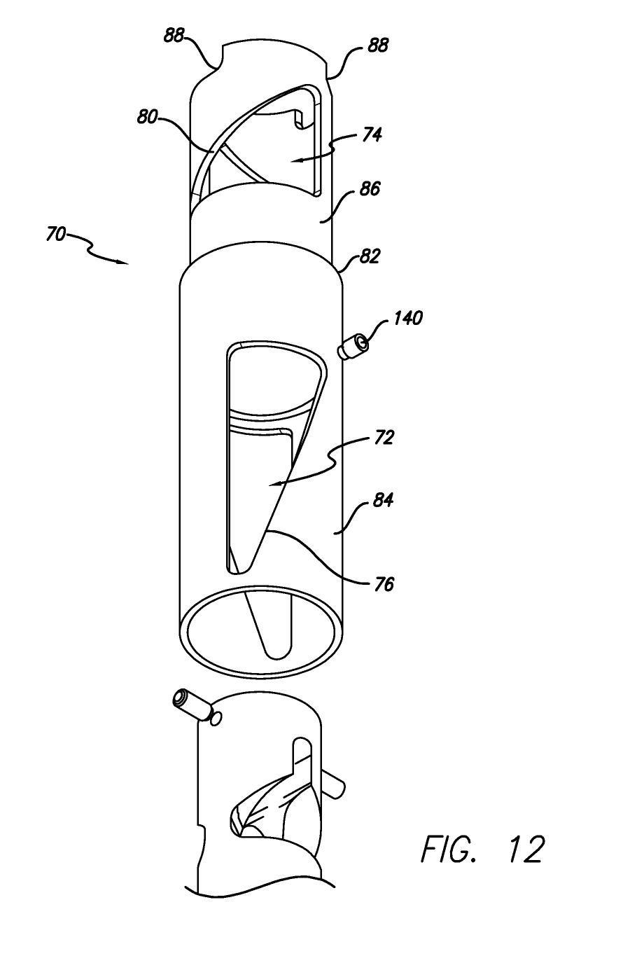

A sleeve 70, as illustrated in FIGS. 5 and 12, is a generally hollow, cylindrical member and is operatively connected to the centering cam 46, as illustrated in FIG. 9. The sleeve 70 is formed of plastic, but can be made of any material sufficient to allow the sleeve to rotate relative to the centering cam 46, the swivel body 90, and the pull-down member 28 in a smooth manner. The sleeve 70 is disposed immediately adjacent to the outer surface of the centering cam 46, adjacent the inner surfaces of the swivel body 90, and immediately adjacent to the inner surface of the pull-down member 28 in a concentric manner and is rotatable relative to each of the three members 28, 46, 90. When assembled, the bottom surface of the sleeve 70 is adjacent to the top surface of the attachment portion 48 of the centering cam 46 in such a manner that the outer surfaces of the sleeve 70 and the attachment portion 48 are concentrically aligned, as shown in FIG. 9.

The sleeve 70 includes at least one lower aperture 72 and at least one upper aperture 74 formed therethrough, as shown in FIGS. 5 and 12. The lower apertures 72 are shaped as generally inverted right triangles, wherein the longest edge of the lower aperture 72 forms a lower cam surface 76. A first ball detent 140 is received in the receiving aperture 35 (FIG. 6) of the pull-down member 28 and extends therefrom such that the first ball detent 140 is adapted to contact the lower cam surface 76 of the sleeve 70 when the flat panel display 14 is adjusted vertically, as illustrated in FIG. 12. In one embodiment, the first ball detent 140 is a roller bearing connected to a dog-point set screw (not shown), wherein the roller bearing contacts the lower cam surface 76. The upper aperture 74 is shaped as a laterally-oriented right triangular aperture, wherein the longest edge of the upper aperture 74 forms an upper cam surface 80. The apertures 72, 74 are shaped to allow for the support mechanism 20 to be rotated, or swiveled, about the vertical axis between about zero and ninety degrees in both the clockwise and counter-clockwise directions relative to the vertical axis 16.

The sleeve 70 includes a seat 82 that separates the lower portion 84 and upper portion 86 of the sleeve 70, as shown in FIG. 12. The diameter of the outer surface of the lower portion 84 is greater than the diameter of the outer surface of the upper portion 86, thereby forming the seat 82 between the two portions 84, 86. The upper portion 86 of the sleeve 70 includes opposing notches 88 formed at the distal end of the upper portion 86. The seat 82 of the sleeve 70 provides a surface to support a swivel body 90, as shown in FIGS. 4 and 9. The swivel body 90 is rotatable relative to the centering cam 46, whereby the sleeve 70 provides a bearing between the swivel body 90 and the centering cam 46.

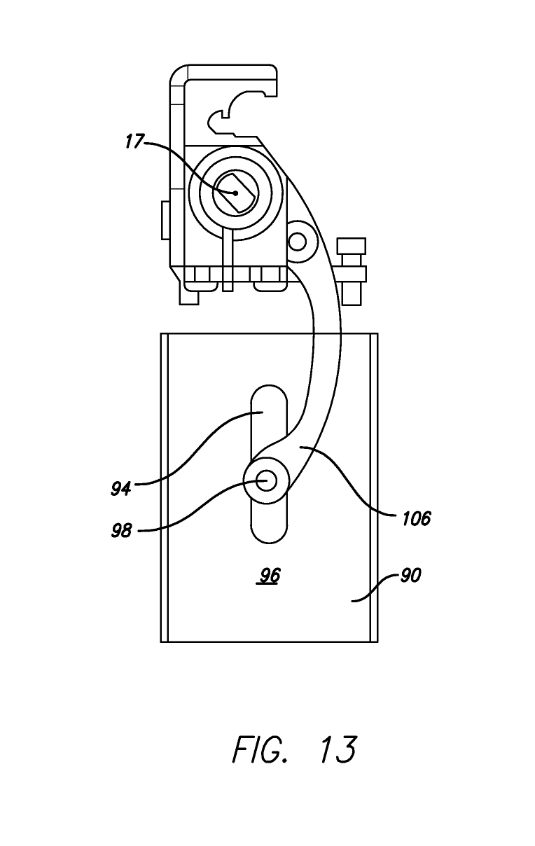

The swivel body 90 is located immediately adjacent to the seat 82 of the sleeve 70 in an abutting manner, as shown in FIG. 9. The bottom surface of the sleeve 70 includes an aperture 92 formed therein such that the aperture 92 receives the guide portion 52 of the centering cam 46, as shown in FIG. 9. An elongated slot 94 is formed in opposing side surface 96 of the swivel body 90, as shown in FIG. 13. The slot 94 is adapted to receive a centering axle 98, wherein the centering axle 98 passes through one of the side surfaces 96 of the swivel body 90, the opposing apertures formed in the centering cam 46, and through the slot 94 in the opposing side surface 96 of the swivel body 90, as shown in FIG. 4, and is oriented in a generally parallel manner with respect to the horizontal axis 17. The opposing distal ends of the centering axle 98 extend beyond the opposing side surfaces 96 of the swivel body 90 in an outward direction.

At least one sleeve bearing is located on the centering axle 98, as illustrated in FIG. 4. The sleeve bearings are disposed about the outer surface of the centering axle 98 to allow the centering axle 98 to move relative to the swivel body 90 and the centering cam 46. In one embodiment, four sleeve bearings, including a pair of outer sleeve bearings 102 and a pair of inner sleeve bearings 104, are disposed on the centering axle 98. A pair of outer sleeve bearings 102 are located at opposing ends of the centering axle 98 and are adapted to provide smooth sliding movement between the centering axle 98 and the slot 94 formed in each side surface 96 of the swivel body 90 as well as providing smooth sliding movement between the centering axle 98 and the upper cam surface 80 of the upper apertures 74 of the sleeve 70. The pair of inner sleeve bearings 104 are disposed adjacent to the outer sleeve bearings 102 and are adapted to provide smooth sliding movement between the centering axle 98 and the first and second cam surfaces 60 of the centering cam 46. The sleeve bearings 102, 104 are disposed along the length of the centering axle 98 in series having a spacer (not shown) located between adjacent sleeve bearings such that the sleeve bearings 102, 104 can rotate about the centering cam 46 without interference from an adjacent sleeve bearing 102, 104. In one embodiment, the centering axle 98 has a constant diameter along the entire length of the centering axle 98. In an alternative embodiment, the centering axle 98 has a stepped contour such that the middle portion of the centering axle 98 has a slightly larger diameter than the adjacent outer portions.

A connecting link 106 is connected to each opposing distal end of the centering axle 98, as shown in FIGS. 4 and 13. The connecting link 106 is a curved, elongated member having an aperture formed in each opposing distal ends. The aperture located at one distal end of each connecting link 106 receives the centering axle 98, and the aperture located at the opposing distal end of each connecting link 106 receives an arm axle 108 that extends between the opposing connecting links 106. The connecting links 106 are connected to the centering axle 98 and the arm axle 108 in a substantially rigid manner such that the rotational forces from the arm axle 108 are transmitted to the centering axle 98 by way of the connecting links 106. The connecting links 106 have a sleeve bearing disposed within each aperture located at the opposing ends of the connecting link 106, thereby allowing the centering axle 98 and arm axle 108 to rotate relative to the connecting links 106 as the support mechanism 20 is adjusted. The connecting links 106 are disposed outside the swivel body 90, and are located adjacent to the opposing side surfaces 96 of the swivel body 90 having the elongated slots 94 formed therein.

In an alternative embodiment, the centering axle 98 is disposed through the centering cam 46, wherein the centering cam 46 includes a single cam surface 60. The centering axle 98 has a single inner sleeve bearing 102 and a single outer sleeve bearing 104 operatively connected thereto for contact with the cam surface 60 and the swivel body 90, respectively. The centering axle 98 is operatively connected to one connecting link 106 located at a distal end of the centering axle 98.

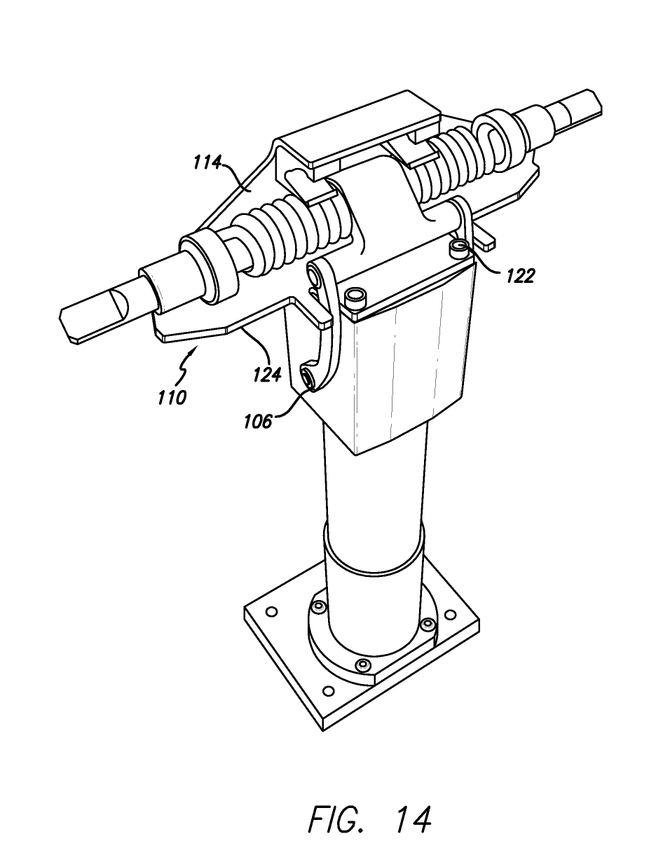

A tilt bracket 110 is attached to the top surface of the swivel body 90, as illustrated in FIG. 4. The tilt bracket 110 is generally u-shaped having a mounting portion 112, a vertical portion 114, and a support portion 116. The mounting portion 112 of the tilt bracket 110 is located immediately adjacent to the top surface of the swivel body 90. The mounting portion 112 includes a pair of cut-outs 118 formed therein in which the connecting links 106 are located, as illustrated in FIG. 14. The mounting portion 112 also includes a pair of apertures 120 (FIG. 4) formed therethrough, and each aperture 120 receives a bolt 122. The bolts 122 attach the tilt bracket 110 to the top surface of the swivel body 90 in a substantially rigid manner. The mounting portion 112 of the tilt bracket 110 includes flanges 124 that extend outwardly from the mounting portion 112 in a generally horizontal manner. The vertical portion 114 of the tilt bracket 110 extends in a transverse direction from the mounting portion 112, and the support portion 116 of the tilt bracket 110 extends in a transverse direction relative to the vertical portion 114, thereby forming a u-shaped bracket, as shown in FIGS. 4 and 14.

In one embodiment, an actuator arm 126 is rigidly connected to an arm axle 108, as shown in FIG. 4. In an alternative embodiment, the actuator arm 126 and the arm axle 108 are formed as a single member. In a further alternative embodiment, the actuator arm 126 forms a hole through which the arm axle 108 passes such that the arm axle 108 is rotatable relative to the actuator arm 126 in an independent manner. The actuator arm 126 extends from the arm axle 108 and receives a tilt axle 128. The tilt axle 128 is an elongated member that is laterally disposed such that it is substantially parallel to the arm axle 98, thereby forming a horizontal axis 17 of rotation about which the flat-panel display 14 can tilt. The actuator arm 126 is operatively connected to the tilt axle 128 such that rotational movement of the tilt axle 128 is transmitted to the arm axle 108 by way of the actuator arm 126. The tilt axle 128 is a generally cylindrical member and passes through the actuator arm 126 such that the tilt axle 128 extends outwardly from the opposing ends of the actuator arm 126. A bearing holder 130 is attached to each flange 124 of the tilt bracket 110, and each bearing holder 130 receives the tilt axle 128. A bearing (not shown) is located between the tilt axle 128 and each of the bearing holders 130 so as to allow the tilt axle 128 to rotate relative to the tilt bracket 110.

At least one torsion spring 132 is located between the actuator arm 126 and each of the bearing holders 130, as shown in FIG. 4. The torsion springs 132 assist in maintaining the user-selected tilt position of the flat-panel display 14. The torsion spring 132 also assists in raising the flat-panel display 14 between a folded-down position and an upright position. The torsion springs 132 act to counterbalance the weight of the flat-panel display 14. Friction bands 137 (FIG. 5) provide resistance to the tilt axle 128 so as to maintain the flat-panel display 14 in a user-selected position. In one embodiment, the bearing holders 130 and the friction bands 137 are formed together to receive the tilt axle 128 such that bearings between the bearing holders 130 and the tilt axle 128 are not necessary.

The opposing distal ends 134 of the tilt axle 128 are flattened, thereby forming a rectangular-shaped receiving member, as shown in FIG. 4. The flat-panel display 14 is secured to the opposing distal ends 134 of the tilt axle 128 such that the vertical, tilt, or rotational forces of the flat-panel display 14 are transferred to the support mechanism 20 by way of the tilt axle 128. The flat-panel display 14 can be operatively connected to the support mechanism 20 by way of a variety of different securing mechanisms including, but not limited to, bolts, screws, or a weld. The securing mechanism for connecting the flat-panel display 14 to the support mechanism 20 must be sufficient to allow the flat-panel display 14 to be tilted and swiveled orientations relative to the base 22.

In operation, the flat-panel display 14 can be tilted, swiveled, raised, lowered, or any combination thereof relative to the base 22 of the support mechanism 20. The flat-panel display 14 has a first operative position in which the flat-panel display 14 directed in a centered, forwardly-facing direction such that it is has not been rotated relative to the base 22. When in the centered position, the flat-panel display 14 is oriented in a substantially vertical manner such that the flat-panel display 14 has no tilt relative to the central, vertical axis 16 of the support mechanism 20. Also, the flat-panel display 14 is located in a lowered position in which the flat-panel display 14 has not been vertically raised relative to the base 22. In one embodiment, the range of movement of the support mechanism 20 allows the flat-panel display 14 to be tilted to a second operative position in which the flat-panel display 14 is oriented in a substantially horizontal, or closed, manner such that the user cannot view the display screen.

The flat-panel display 14 is rotatable relative to the base 22 in a swiveling manner. In operation, when the user wants to adjust the rotation of the flat-panel display 14 relative to the centered position, as represented as arrow B in FIG. 3, the flat-panel display 14 is rotated about the vertical axis 16 of the support mechanism 20. The rotational forces are transferred from the flat-panel display 14 to the tilt axle 128. The tilt bracket 110 prevents the tilt axle 128 from rotating relative to the swivel body 90 such that the rotational forces from the flat-panel display 14 are transferred to the tilt bracket 110 by way of the bearing holders 130. The rotational forces then transfer from the tilt bracket 110 to the swivel body 90 through the rigid connection therebetween, and the swivel body 90 rotates about the vertical axis 16 of the support mechanism 20. As the swivel body 90 rotates, the centering axle 98 that passes through the swivel body 90 and the guide portion 52 of the centering cam 46 acts upon the slot 94 formed in each of the opposing side surfaces 96 of the swivel body 90, thereby causing the centering axle 98 to rotate about the vertical axis 16 of the support mechanism 20. As the centering axle 98 rotates, the inner sleeve bearings 104 contact the cam surfaces 60 formed in the guide portion 52 of the centering cam 46. The cam surfaces 60 of the guide portion 52 of the centering cam 46 allows for a rotational range of movement such that the flat-panel display 14 can rotate clockwise and counter-clockwise relative to vertical axis 16. The rotational range of movement provided by the first and second cam surfaces 60 can be between about zero and ninety degrees in both the clockwise and counter-clockwise direction about the vertical axis 16 relative to when the flat-panel display 14 is at a centered position.

The flat-panel display 14 has a centered position relative to the base 22 when rotated about the vertical axis 16. A pair of first ball detent 140 is attached to the centering cam 46, as illustrated in FIGS. 5 and 12. The first ball detent 140 includes a cylindrical body and a roller bearing located at the end of the cylindrical body. Each first ball detent 140 extends outward from the outer surface of the centering cam 46 and is disposed within the notch 88 (FIG. 12) in the sleeve 70. As the flat-panel display 14 is rotated about the vertical axis 16, each first ball detent 140 translates within an opposing notch 88 of the sleeve 70. The swivel body 90 includes an aperture 142, as shown in FIG. 9, formed through each surface adjacent to the opposing side surfaces 96. Each aperture 142 receives a first ball detent 140 when the flat-panel display 14 is located at the centered position relative to the base 22. When the roller bearing of the first ball detent 140 is received within the aperture 142 in the swivel body 90, a tactile feedback is provided to the user to indicate that the flat-panel display 14 is located in the centered position.

The flat-panel display 14 is tiltable relative to the upright position in which the display is substantially parallel with the vertical axis 16 of the support mechanism 20. The tilting movement of the flat-panel display 14 about the horizontal axis 17 is independent of the rotational movement about the vertical axis 16 when the flat-panel display 14 is in a centered position. In operation, when the user wants to adjust the tilt angle of the flat-panel display 14 relative to the centered position, as represented as arrow A in FIG. 3, the flat-panel display 14 is pulled forwardly or pushed rearwardly relative to the horizontal axis 17. When the flat-panel display 14 is pulled forwardly or pushed rearwardly, the tilt axle 128 is rotated about the horizontal axis 17. The tilt axle 128 is allowed to rotate by way of the bearings located in the bearing holders 130. The torsion springs 132 and friction bands 137 generate rotational resistance yet provide support so as to maintain the flat-panel display 14 in the user-selected tilt position. Rotation of the tilt axle 128 causes the actuator arm 126 to rotate, thereby causing the arm axle 108 to be raised relative to the mounting portion 112 of the tilt bracket 110. As the arm axle 108 is raised, the connecting links 106 raise the centering axle 98, thereby causing the inner sleeve bearings 104 to rotate about the centering axle 98 and travel along the cam surfaces 60 of the centering cam 46. As the centering axle 98 translates along the cam surfaces 60 of the centering cam 46, the outer sleeve bearings 102 rotate to allow the centering axle 98 to translate within the slot 94 formed in each of the side surfaces 96 of the swivel body 90. The flat-panel display 14 can be tilted between about twenty degrees rearward and one hundred ten degrees forward relative to the fully upright position.

The flat-panel display 14 is tiltable when the display is rotated away from the centered position. The support mechanism 20 can provide for self-centering of the flat-panel display 14 when the display is in a rotated position by tilting the flat-panel display 14 toward the closed, or substantially horizontal, position. When the flat-panel display 14 is located in a position that is swiveled away from the centered position, and the user causes the flat-panel display 14 to be tilted toward a forward position, the flat-panel display 14 is swiveled toward the centered position. The first and second cam surfaces 60 have an inverted-funnel shape so as to allow for simultaneous rotation and tilt of the flat-panel display 14 as a result of the inner sleeve bearings 104 translating along the first and second cam surfaces 60. As the centering axle 98 is raised relative to the centering cam 46, the first and second cam surfaces 60 cause the centering axle 98 to be rotated about the vertical axis 16, thereby causing the flat-panel display 14 to be rotated toward the centered position as the flat-panel display 14 is rotated forwardly in a simultaneous manner. Once the flat-panel display 14 reaches the centered position, continued tilt of the flat-panel display 14 causes the centering axle 98 to translate along the substantially vertical, straight portion of the first and second cam surfaces 60. When the flat-panel display 14 is actuated to the closed position, the flat panel display 14 is centered with respect to the rotational movement and tilted to the forwardmost position.

At least one snap detent 144 is disposed adjacent to the vertical portion 114 and support portion 116 of the tilt bracket 110 as well as the torsion springs 132, as illustrated in FIG. 4. The snap detents 144 receive the arm axle 108 when the flat-panel display 14 is tilted forward to the closed position. The snap detents 144 secure the flat-panel display 14 in the closed position so as to prevent the flat-panel display 14 from rotating toward an upright position when the component stand 10 is being transported between locations.

The height of the flat-panel display 14 is also adjustable relative to the base 22. The height adjustment of the flat-panel display 14 is independent of the rotational and tilt movements of the flat-panel display 14. In operation, as the user lifts or lowers the flat-panel display 14 relative to the base 22, the swivel body 90 is raised or lowered in a corresponding manner by way of the tilt axle 128 applying an up-force or down-force to the bearing holders 130. The up-force or down-force is transferred to the tilt bracket 110 which is in turn transferred to the swivel body 90 such that the swivel body 90 translates relative to the pull-down member 28. The up-force or down-force is also transmitted to the centering axle 98 by way of the connecting links 106. The up-force or down-force is transferred from the tilt bracket 110 to the gas spring 62 by way of the knob 58 that is received in a keyhole aperture in the mounting portion 112 of the tilt bracket 110, thereby causing the swivel body 90, sleeve 70, centering cam 46, and the spline nut 42 to be raised relative to the base 22 and spline shaft 36. Because the spline nut 42 is fixedly attached to the centering cam 46, the spline nut 42 is raised and lowered in conjunction with the centering cam 46. As the centering cam 46 and the spline nut 42 are raised or lowered, the first followers 55 translate in the opposing slots 34 of the pull-down member 28. The range of vertical adjustment of the flat-panel display 14 is defined by the slots 34 of the pull-down member 28. The slot 34 is about two and one-quarter inches (2¼″) in length such that the height of the flat-panel display 14 can be adjusted accordingly.

The flange 33 of the pull-down member 28 includes a second ball detent 56, as shown in FIGS. 4-5, that corresponds to a hole 57 formed in the attachment portion 48 of the centering cam 46. The hole 57 has generally the same shape as the second ball detent 56 such that when the support mechanism 20 is lowered to the lowest adjustable height, the second ball detent 56 is received in the hole 57, thereby securing the support mechanism 20 in the lowest adjustable height. When adjusting the height of the support mechanism 20, the user can feel when the second ball detent 56 is received in the hole 57, thereby providing tactile feedback to the user to indicate when the support mechanism 20 has been actuated to the lowest adjustable height.

The support mechanism 20 allows for the self-centering of the flat-panel display 14 when the flat-panel display 14 is actuated toward the closed position. The shape of the cam surfaces 60, 76, 80 ensure that the flat-panel display 14 is rotated toward the forward-directed, centered position about the vertical axis 16 as well as lowered to the lowest position relative to the base 22 when the flat-panel display 14 is actuated to the closed position. The cam surfaces 60, 76, 80 act in conjunction with the tilting movement of the flat-panel display 14 to ensure that the flat-panel display 14 is centered when it reaches the closed position. Without self-centering the flat-panel display 14, the flat-panel display 14 would be improperly aligned relative to the base 22 in a rotational, or swiveled, manner such that the flat-panel display may contact components surrounding the support mechanism 20 as a result of the flat-panel display 14 not being centered. When the flat-panel display 14 is rotated forward to about forty degrees from fully upright, the flat-panel display is rotationally centered about the vertical axis 16.

In one embodiment, the support mechanism 20 is lowered to the lowest adjustable height when the flat-panel display 14 is moved to the closed position. A set screw 150 (FIG. 4) is located within the receiving aperture 35 of the pull-down member 28, as shown in FIG. 6. The set screw 150 includes a cylindrical body and a roller bearing located at the end of the cylindrical body adjacent to the sleeve 70 when assembled. The set screw 150 extends inwardly from the receiving aperture 35 of the pull-down member 28 and is received by the lower aperture 72 of the sleeve 70 such that the set screw 150 is in sliding engagement with the lower cam surface 76 of the sleeve 70, as illustrated in FIGS. 5 and 12. In operation, as the flat-panel display 14 is tilted toward the closed position, rotation of the tilt axle 128 causes the arm axle 108 to be raised relative to the mounting portion 112 of the tilt bracket 110. As the arm axle 108 is raised, the connecting links 106 are actuated such that the centering axle 98 moves upward within the elongated slots 94 located in the swivel body 90. As the centering axle 98 moves upward, the outer sleeve bearings 102 are in sliding contact with the upper cam surface 80 of the upper apertures 74 of the sleeve 70. The upward movement of the centering axle 98 against the upper cam surface 80 of the sleeve 70 causes the sleeve 70 to rotate about the vertical axis 16. As the sleeve 70 rotates about the vertical axis, the set screw 150 bears against the lower cam surface 76 of the lower aperture 72 of the sleeve 70 such that the set screw 150 translates along the lower cam surface 76 from the lower portion of the lower cam surface 76 to the upper portion of the lower cam surface 76 in a manner that causes the sleeve to be lowered relative to the base 22, thereby pulling down the swivel body 90 as well as the members attached thereto to the lowest adjustable height.

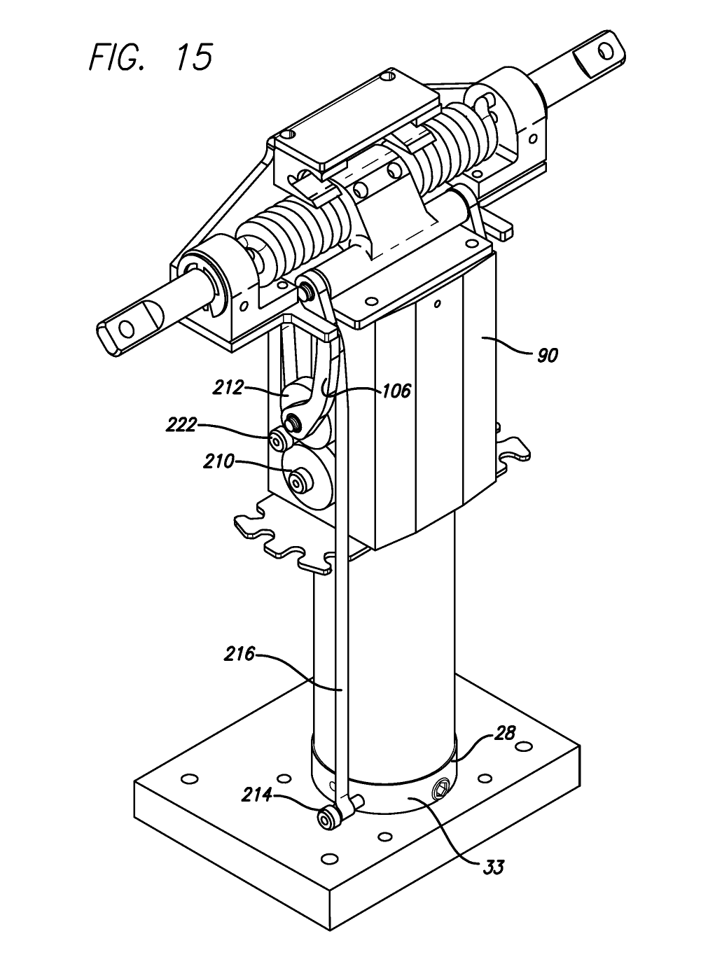

In an alternative embodiment, a first pulley 210 is operatively connected to the swivel body 90 such that the first pulley 210 is rotatable relative to the swivel body 90, as illustrated in FIG. 15. A second pulley 212 is rotatably connected to the centering axle 98. A shoulder screw 214 is connected to the flange 33 of the pull-down member 28, and the shoulder screw 214 receives one end of a band 216. The band 216 is made of metal, but any other material sufficient to withstand the stresses associated with the raising and lowering, as well as the rotation, of the support mechanism 20 can be used. A distal end of the band 216 is connected to the shoulder screw 214 and the second distal end 220 of the band 216 is fixedly attached to the swivel body 90 by way of a pin 222. The band 216 has a fixed length and forms a loop about the first and second pulleys 210, 212 such that the band 216 extends from the pin 222 over the top of the second pulley 212, under the first pulley 210, over the top of the second pulley 212 adjacent to the portion of the band previously passed over the top of the second pulley 212, and downward to the shoulder screw 214. In operation, as the flat-panel display is tilted toward the closed position, the connecting link 106 causes the second pulley 212 to move away from the first pulley 210 such that the loop of the band 216 surrounding the first and second pulleys 210, 212 increases, thereby shortening the length of the band 216 that extends between the top of the second pulley 212 and the shoulder screw 214. As the length of the band 216 extending between the top of the second pulley 212 and the shoulder screw 214 decreases, the swivel body 90 and the members attached thereto are pulled downward toward the base 22.

In one embodiment, a microswitch (not shown) is attached to the tilt bracket 110 adjacent to the bearing holder 130. The microswitch can be operatively connected to the power supply for the flat-panel display 14 such that the rotation of the tilt axle 128 caused by the tilting of the flat-panel display 14 toward the closed position activates the microswitch so as to shut off the power to the flat-panel display 14. The microswitch can also be operatively connected to other electrical components such that tilting of the flat-panel display 14 toward the closed position actuates the microswitch, thereby causing another function to be performed including, but not limited to, turning off a light or turning off the ultrasound system.

While preferred embodiments of the invention have been described, it should be understood that the invention is not so limited and modifications may be made without departing from the invention. The scope of the invention is defined by the appended claims, and all devices that come within the meaning of the claims, either literally or by equivalence, are intended to be embraced therein.

I (We) claim:

1-16. (canceled)

17. A diagnostic ultrasound system comprising:
a component cart in which electronic components of said ultrasound system are located;
a flat-panel display operatively connected to said component cart and said ultrasound system, wherein said flat-panel display is attached to an adjustable mechanism such that said flat-panel display is self-centerable.

18. The diagnostic ultrasound system of claim 17, wherein said adjustable mechanism is self-centering when tilting said flat-panel display from a first operative position to a second operative position.

19. The diagnostic ultrasound system of claim 18, wherein said second operative position is a closed position.

20. The diagnostic ultrasound system of claim 17, wherein said adjustable mechanism includes a gas spring operatively supporting said vertical adjustability of said flat-panel display.

21-25. (canceled)

26. The diagnostic ultrasound system of claim 17, wherein said adjustable mechanism includes:
a base operable to receive a centering cam, wherein said centering cam includes at least one cam surface;
a centering axle operable to contact said at least one cam surface of said centering cam;
at least one connecting link operably connected to said centering axle and an actuator arm;
wherein said actuator arm is operatively connected a tilt axle, wherein said tilt axle is operably connected to a swivel body and said tilt axle is attachable to the flat-panel display; and
wherein said flat-panel display is self-centering relative to said base.

27. The diagnostic ultrasound system of claim 26, wherein said centering cam is translatable relative to said base.

28. The diagnostic ultrasound system of claim 27, wherein a spline shaft is attached to said base and said centering cam is operable to receive said spline shaft.

29. The diagnostic ultrasound system of claim 28, wherein said centering cam is attached to a spline nut and said spline nut slidingly engages said spline shaft thereby allowing said centering cam to translate relative to said base.

30. The diagnostic ultrasound system of claim 29, wherein said centering cam is operably engaged with a pull-down member attached to said base and said pull-down member operably limits translation of said centering cam relative to said base.

31. The diagnostic ultrasound system of claim 30, wherein said pull-down member includes at least one slot in which a follower attached to said centering cam is disposed.

32. The diagnostic ultrasound system of claim 26, wherein said swivel body is rotatable relative to said base.

33. The diagnostic ultrasound system of claim 32, wherein rotation of said flat-panel display causes said swivel body to rotate relative to said base.

34. The diagnostic ultrasound system of claim 33, wherein rotation of said swivel body causes said centering axle to translate along said at least one cam surface of said centering cam.

35. The diagnostic ultrasound system of claim 34, wherein a sleeve bearing is disposed on said centering axle, and said sleeve bearing rotates about said centering axle such that said centering axle translates along said at least one cam surface.

36. The diagnostic ultrasound system of claim 26, wherein said flat-panel display is tiltable between a first operative position and a second operative position.

37. The diagnostic ultrasound system of claim 36, wherein said first operative position is a centered position such that said flat-panel display is oriented in a substantially vertical manner.

38. The diagnostic ultrasound system of claim 37, wherein said second operative position is a closed position such that said flat-panel display is oriented in a substantially horizontal manner.

39. The diagnostic ultrasound system of claim 17, wherein said flat-panel display is tiltable between about zero and ninety degrees relative to a vertical orientation.

40. The diagnostic ultrasound system of claim 17, wherein said flat-panel display can be adjusted vertically from a lowered position to about two and one-quarter inches vertically from said lowered position.

41. The diagnostic ultrasound system of claim 17, wherein said flat-panel display is rotatable between about zero and ninety degrees in both the clockwise and counter-clockwise direction relative to a centered position.
